(19) United States
(12) Patent Application Publication
(10) Pub. No.: US 2023/0294241 A1
(43) Pub. Date: Sep. 21, 2023

(54) POLISHING METHOD AND POLISHING APPARATUS

(71) Applicant: EBARA CORPORATION, Tokyo (JP)

(72) Inventor: Ban ITO, Tokyo (JP)

(21) Appl. No.: 18/119,778

(22) Filed: Mar. 9, 2023

(30) Foreign Application Priority Data
Mar. 15, 2022 (JP) 2022-039853

(51) Int. Cl. B24B 53/12; B24B 53/017; B24B 57/02; B24B 37/005; B24B 37/04

(52) U.S. Cl. CPC B24B 53/12; B24B 37/005; B24B 37/044; B24B 53/017; B24B 57/02

(57) ABSTRACT

A polishing method capable of stabilizing a polishing process of a substrate is disclosed. In the polishing method, a fine bubble liquid is supplied onto a polishing pad after finishing polishing the substrate.

### CROSS REFERENCE TO RELATED APPLICATION

This document claims priority to Japanese Patent Application No. 2022-039853 filed Mar. 15, 2022, the entire contents of which are hereby incorporated by reference.

### BACKGROUND

A planarization technology for device surfaces is becoming increasingly important in a semiconductor device manufacturing process. The most important planarization technology is a chemical mechanical polishing (CMP). In this chemical mechanical polishing (hereinafter referred to as CMP), a polishing is performed using a polishing apparatus in which a polishing liquid (slurry) containing abrasive grains such as silica (SiO2) and ceria (CeO2) is supplied to a polishing pad while a polishing head holding a wafer or other substrate slides against a polishing surface of the polishing pad.

After polishing the substrate, a liquid (e.g., pure water) is supplied on the polishing pad to stabilize a polishing process of the substrate. For example, the substrate is water polished to remove polishing debris and abrasive grains of the polishing liquid from a surface of the substrate, or the polishing pad is dressed to prepare a surface condition of the polishing pad for polishing the next substrate.

However, if a polishing pressure on the substrate is increased or a processing time is lengthened during water polishing of the substrate in order to stabilize the polishing process of the substrate, not only may a throughput of the substrate be compromised, but also defects may occur on the substrate.

In order to stabilize the polishing process of the substrate, the life of the polishing pad may be shortened and a polishing rate and a profile of the substrate may be adversely affected if a dressing load is increased or a rotational speed of the polishing table is increased during dressing the polishing pad to remove more of the polishing pad.

### SUMMARY

Therefore, there are provided a polishing method and a polishing apparatus capable of stabilizing the polishing process of the substrate.

Embodiments, which will be described below, relate to a polishing method and a polishing apparatus.

In an embodiment, there is provided a polishing method comprising: rotating a polishing table configured to support a polishing pad; pressing a substrate held by a polishing head against the polishing pad while supplying a polishing liquid onto the polishing pad to polish the substrate; and supplying a fine bubble liquid onto the polishing pad after finishing polishing the substrate.

In an embodiment, the fine bubble liquid is supplied from one or more nozzles of a nozzle arm configured to pivot in a radial direction of the polishing table onto the polishing pad.

In an embodiment, the polishing method comprising supplying the fine bubble liquid onto the polishing pad while pressing the substrate against the polishing pad to polish the substrate with the fine bubble liquid.

In an embodiment, the fine bubble liquid comprises an ultrafine bubble liquid having a bubble diameter of 1 micrometer or less.

In an embodiment, the polishing method comprising: transporting the substrate from the polishing pad after finishing polishing the substrate; moving a dresser on the polishing pad after transporting the substrate to dress the polishing pad; and supplying the fine bubble liquid onto the polishing pad during dressing the polishing pad.

In an embodiment, the fine bubble liquid comprises a microbubble liquid having a bubble diameter from 1 micrometer to 100 micrometers or less.

In an embodiment, the fine bubble liquid is supplied from an atomizer extending in a radial direction of the polishing table onto the polishing pad.

In an embodiment, the polishing method comprising: transporting the substrate from the polishing pad after finishing polishing the substrate; moving the polishing head to a retracted position arranged outside the polishing pad after transporting the substrate; and supplying the fine bubble liquid to the polishing head arranged in the retracted position to clean the polishing head.

In an embodiment, the fine bubble liquid has bubbles generated from a gas corresponding to a structure of the substrate among a plurality of kinds of gases.

In an embodiment, the fine bubble liquid is generated by a pressurized dissolution method for dissolving the gas into a liquid.

In an embodiment, the polishing method comprising: counting the number of bubbles contained in the fine bubble liquid by a particle counter; and supplying the fine bubble liquid after the number of bubbles reaches a predetermined reference number.

In an embodiment, there is provided a polishing apparatus comprising: a polishing table configured to support a polishing pad; a polishing head configured to press a substrate against the polishing pad; a liquid supply mechanism configured to supply a liquid onto the polishing pad, the liquid supply mechanism comprising a fine bubble liquid supply device configured to supply a fine bubble liquid onto the polishing pad after finishing polishing the substrate; and a controller configured to control an operation of the liquid supply mechanism.

In an embodiment, the fine bubble liquid supply device comprises: a nozzle arm configured to pivot in a radial direction of the polishing table; and one or more fine bubble liquid nozzles, arranged to the nozzle arm, configured to supply the fine bubble liquid onto the polishing pad.

In an embodiment, the fine bubble liquid supply device is configured to supply an ultrafine bubble liquid, as the fine bubble liquid, having a bubble diameter of 1 micrometer or less onto the polishing pad while pressing the substrate against polishing pad by the polishing head.

In an embodiment, the polishing apparatus comprises a dressing device configured to dress the polishing pad, and electrically connected to the controller, the controller moves a dresser on the polishing pad by operating the dressing device to dress the polishing pad after finishing polishing the substrate and transporting the substrate, and the fine bubble liquid supply device supplies a microbubble liquid, as the fine bubble liquid, having a bubble diameter from 1 micrometer to 100 micrometers or less onto the polishing pad during dressing the polishing pad.

In an embodiment, the polishing apparatus comprises an atomizer extending in a radial direction of the polishing table, and the fine bubble liquid supply device supplies the fine bubble liquid from the atomizer onto the polishing pad.

In an embodiment, the controller moves the polishing head to a retracted position arranged outside the polishing pad after finishing polishing the substrate and transporting the substrate, and the fine bubble liquid supply device supplies the fine bubble liquid to the polishing head arranged in the retracted position to clean the polishing head.

In an embodiment, the fine bubble liquid has bubbles generated from a gas corresponding to a structure of the substrate among a plurality of kinds of gases.

In an embodiment, the fine bubble liquid supply device comprises a fine bubble liquid generator configured to generate the fine bubble liquid by a pressurized dissolution method for dissolving the gas into a liquid.

In an embodiment, the fine bubble liquid supply device comprises a particle counter configured to count the number of bubbles contained in the fine bubble liquid, and the fine bubble liquid supply device supplies the fine bubble liquid after the number of bubbles reaches a predetermined reference number based on the number of bubbles counted by the particle counter.

By supplying the fine bubble liquid having high cleaning power onto the polishing pad after finishing polishing the substrate, the polishing process of the substrate can be stabilized.

### BRIEF DESCRIPTION OF THE DRAWINGS

FIG. 1 is a view showing an embodiment of a polishing apparatus;

FIG. 2 is a view showing a liquid supply mechanism;

FIG. 3 is a view showing a fine bubble liquid generator;

FIG. 4 is a view showing another embodiment of the fine bubble liquid supply device;

FIG. 5 is a view showing another embodiment of the fine bubble liquid generator;

FIG. 6 is a view showing a processing flow of a substrate by a controller;

FIG. 7 is a view showing another embodiment of the polishing apparatus; and

FIG. 8 is a view showing another embodiment of the processing flow of the substrate by the controller.

### DESCRIPTION OF EMBODIMENTS

Embodiments will be described below with reference to the drawings. In the drawings described below, identical or equivalent components will be marked with the same symbol and redundant explanations will be omitted.

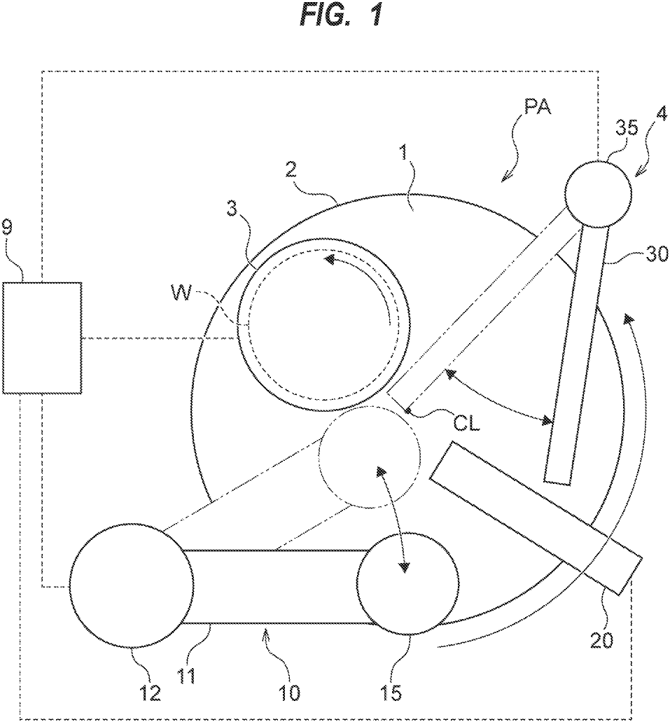

FIG. 1 is a view showing an embodiment of a polishing apparatus. As shown in FIG. 1, a polishing apparatus PA includes a polishing table 2 that supports a polishing pad 1, a polishing head 3 that presses a substrate W such as a wafer onto the polishing pad 1, and a liquid supply mechanism 4 for supplying a liquid onto the polishing pad 1. The liquid supplied from the liquid supply mechanism 4 onto the polishing pad 1 is a polishing liquid (slurry), pure water (DIW), or a fine bubble liquid (to be described later).

The polishing table 2 is coupled to a table motor (not shown) that rotates the polishing table 2 via a table shaft (not shown) that supports the polishing table 2. The polishing pad 1 is attached to an upper surface of the polishing table 2, and the upper surface of the polishing pad 1 constitutes a polishing surface for polishing the substrate W.

The polishing head 3 is fixed to a lower end of a polishing head shaft (not shown). The polishing head 3 is configured to be able to hold the substrate W by vacuum suction on a lower surface of the polishing head 3. The polishing head shaft is coupled to a rotation mechanism (not shown), and the polishing head 3 is rotated through the polishing head shaft by this rotation mechanism.

The polishing apparatus PA further includes a dressing device 10 for dressing the polishing pad 1. The dressing device 10 includes a dresser 15 that is slid against the polishing surface of the polishing pad 1, a dresser arm 11 that supports the dresser 15, and a dresser swivel axis 12 that swivels the dresser arm 11. The dresser swivel axis 12 is arranged outside of the polishing pad 1.

As the dresser arm 11 swivels, the dresser 15 oscillates over the polishing surface. a lower surface of the dresser 15 constitutes a dressing surface consisting of a number of abrasive grains such as diamond particles. The dresser 15 rotates while oscillating over the polishing surface, and dresses the polishing surface by slightly scraping the polishing pad 1.

The polishing apparatus PA further includes an atomizer 20 that injects a cleaning liquid (more specifically, the fine bubble liquid described later) onto the polishing surface of the polishing pad 1 to clean the polishing surface. The atomizer 20 extends along a radial direction of the polishing pad 1 (or polishing table 2), and is arranged above the polishing surface of the polishing pad 1. The atomizer 20 removes polishing dust and abrasive grains contained in the polishing liquid from the polishing surface of the polishing pad 1 by injecting a large flow rate of cleaning liquid onto the polishing surface. The atomizer 20 injects a large flow rate of cleaning liquid onto the polishing surface even when the dresser 15 is dressing the polishing surface.

The polishing apparatus PA includes a controller 9 that controls operations of components of the polishing apparatus PA (e.g., polishing table 2, polishing head 3, liquid supply mechanism 4, dressing device 10, and atomizer 20). The components of the polishing apparatus PA are electrically connected to the controller 9. Therefore, the controller 9 can control the operations of the components of the polishing apparatus PA.

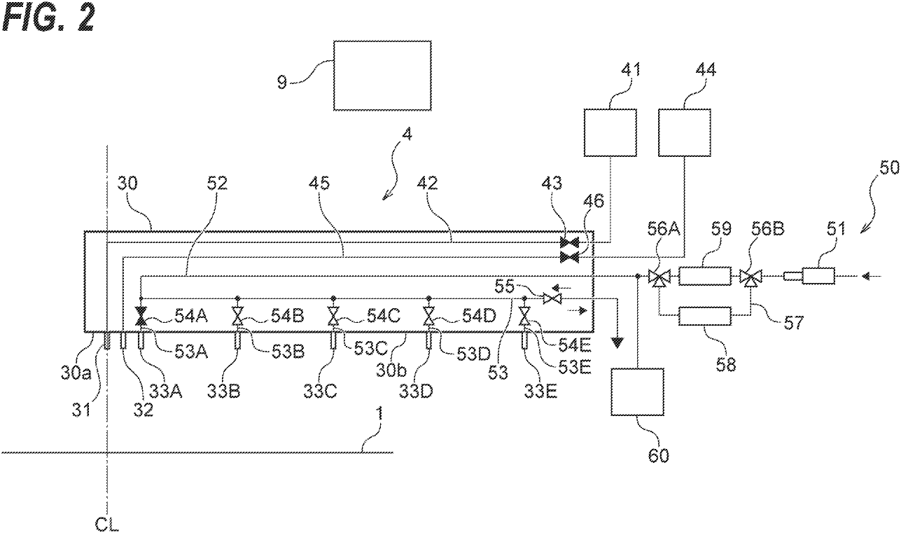

FIG. 2 is a view showing the liquid supply mechanism. As shown in FIG. 2, the liquid supply mechanism 4 includes a nozzle arm 30 movable in a radial direction of the polishing table 2, a slurry nozzle 31 arranged at a tip portion 30a of the nozzle arm 30, and a pure water nozzle 32 and the fine bubble liquid nozzles 33A, 33B, 33C, 33D, and 33E. The pure water nozzle 32 and the fine bubble liquid nozzles 33A, 33B, 33C, 33D, and 33E are arranged at an arm portion 30b of the nozzle arm 30.

The nozzle arm 30 is coupled to a nozzle swivel shaft 35 that swivels the nozzle arm 30 (see FIG. 1). The nozzle swivel shaft 35 is arranged outside of the polishing pad 1. The nozzle arm 30 is configured to be movable between a retracted position outside the polishing pad 1 and a treatment position above the polishing pad 1 by driving the nozzle swivel shaft 35 (more specifically, a motor coupled to the nozzle swivel shaft 35).

As shown in FIG. 2, when the nozzle arm 30 is in the treatment position, the tip portion 30a of the nozzle arm 30 is arranged above a center CL of the polishing pad 1. Therefore, the slurry nozzle 31 arranged on the tip portion 30a of the nozzle arm 30 is arranged above the center CL of the polishing pad 1 so that an inject port of the slurry nozzle 31 is facing the center CL of the polishing pad 1.

When the nozzle arm 30 is in the treatment position, each of the fine bubble liquid nozzles 33A to 33E is arranged above an area between the center CL of the polishing pad 1 and a periphery of the polishing pad 1 so that an inject port of each of the fine bubble liquid nozzles 33A to 33E is facing the area. The pure water nozzle 32 is arranged adjacent to the slurry nozzle 31, and the fine bubble liquid nozzle 33A is arranged adjacent to the pure water nozzle 32.

The fine bubble liquid nozzles 33A to 33E are arranged in this order from a tip side (i.e., the tip portion 30a) of the nozzle arm 30 toward a base side of the nozzle arm 30. Each of the fine bubble liquid nozzles 33A to 33E may have a single tube shape or a spray nozzle shape.

In the embodiment shown in FIG. 2, the liquid supply mechanism 4 includes a plurality of (more specifically, five) fine bubble liquid nozzles, but the number of fine bubble liquid nozzles is not limited to this embodiment. In one embodiment, the liquid supply mechanism 4 may include one fine bubble liquid nozzle or two or more fine bubble liquid nozzles.

The liquid supply mechanism 4 includes a slurry line 42 connected to the slurry nozzle 31, an on-off valve 43 that opens and closes the slurry line 42, and a slurry supply source 41 that supplies slurry to the slurry nozzle 31 through the slurry line 42. Similarly, the liquid supply mechanism 4 includes a pure water line 45 connected to the pure water nozzle 32, an on-off valve 46 that opens and closes the pure water line 45, and a pure water supply source 44 that supplies pure water to the pure water nozzle 32 through the pure water line 45.

The on-off valves 43 and 46 are electrically connected to the controller 9. When the controller 9 opens the on-off valve 43, slurry is supplied from the slurry supply source 41 to the slurry nozzle 31 through the slurry line 42. Similarly, when the controller 9 opens the on-off valve 46, pure water is supplied to the pure water nozzle 32 from the pure water supply source 44 through the pure water line 45.

As shown in FIG. 2, the liquid supply mechanism 4 includes a fine bubble liquid supply device 50 that supplies the fine bubble liquid to each of the fine bubble liquid nozzles 33A to 33E. The fine bubble liquid supply device 50 includes a fine bubble liquid supply line 52 connected to the fine bubble liquid nozzle 33A, an injection nozzle 51 connected to the fine bubble liquid supply line 52, a fine bubble liquid return line 53 connected to each of the fine bubble liquid supply line 52 and each of fine bubble liquid nozzles 33B to 33E.

The fine bubble liquid supply system 50 includes a bypass line 57 connected to the fine bubble liquid supply line 52, a microbubble filter 59 connected to the fine bubble liquid supply line 52, and an ultrafine bubble filter 58 connected to the bypass line 57.

The fine bubble liquid supply system 50 includes three-way valves 56A, 56B that connect the bypass line 57 to the fine bubble liquid supply line 52. Each of the three-way valves 56A, 56B is electrically connected to the controller 9. By operating each of the three-way valves 56A, 56B, the controller 9 can switch a flow of liquid (more specifically, a mixed liquid described below) injected from the injection nozzle 51 between a flow through the microbubble filter 59 and a flow through the ultrafine bubble filter 58.

The microbubble filter 59 allows a passage of the microbubble liquid having a bubble diameter from 1 micrometer to 100 micrometers or less, and captures (removes) bubbles larger than the microbubbles. Therefore, when the liquid injected from the injection nozzle 51 passes through the microbubble filter 59, the microbubble liquid having a bubble diameter from 1 micrometer to 100 micrometers or less is supplied.

The ultrafine bubble filter 58 allows an ultrafine bubble liquid with a bubble diameter of 1 micrometer or less to pass through, and captures (removes) bubbles larger in size than ultrafine bubbles. Therefore, when the liquid injected from the injection nozzle 51 passes through the ultrafine bubble filter 58, the ultrafine bubble liquid with a bubble diameter of 1 micrometer or less is supplied.

In this manner, the fine bubble liquid supply device 50 can supply the microbubble liquid and the ultrafine bubble liquid. In this specification, the fine bubble liquid is a superordinate concept with the microbubble liquid and the ultrafine bubble liquid, and the ultrafine bubble liquid has a smaller bubble diameter than the microbubble liquid.

The fine bubble has a property of floating in water for a long time, and has a large specific surface area. Furthermore, the fine bubble has hydrophobicity and lipophilicity. The fine bubble liquid having such fine bubbles has the property of promoting a chemical reaction at the interface, and being easily adsorbed on the surface of hydrophobic substances such as oils and fats.

The fine bubble liquid supply device 50 may further include a particle counter 60 arranged downstream of the three-way valve 56A in the flow direction of the fine bubble liquid. The particle counter 60 is configured to count the number of bubbles contained in the fine bubble liquid. Therefore, based on the number of bubbles measured by the particle counter 60, the fine bubble liquid supply device 50 may supply the fine bubble liquid from each of the fine bubble liquid nozzles 33A to 33E after the number of bubbles contained in the fine bubble liquid reaches a predetermined reference number. A fine-bubble liquid having bubbles satisfying a predetermined reference number can fully exhibit its properties.

As shown in FIG. 2, the ultrafine bubble filter 58 and the microbubble filter 59 are arranged adjacent to the nozzle arm 30 (more specifically, fine bubble liquid nozzles 33A to 33E). If the distance between the filters 58, 59 and the fine bubble liquid nozzles 33A to 33E is large, bubbles contained in the fine bubble liquid disappear while the fine bubble liquid moves to the fine bubble liquid nozzles 33A to 33E. In this embodiment, such an arrangement can reliably prevent the bubbles contained in the fine bubble liquid from disappearing.

The fine bubble liquid return line 53 includes branch lines 53A, 53B, 53C, 53D and 53E connected to the fine bubble liquid nozzles 33A to 33E. The fine bubble liquid supply device 50 includes on-off valves 54A, 54B, 54C, 54D and 54E connected to the branch lines 53A, 53B, 53C, 53D and 53E, and the on-off valve 55 connected to the fine bubble liquid return line 53. The on-off valves 54A, 54B, 54C, 54D, 54E and the on-off valve 55 are electrically connected to the controller 9. The controller 9 can control the operation of each of the on-off valves 54A, 54B, 54C, 54D, and 54E and the operation of the on-off valve 55.

When the fine bubble liquid is supplied from the fine bubble liquid nozzles 33A to 33E, the controller 9 opens the on-off valves 54A to 54E, and closes the on-off valve 55. By this operation, the fine bubble liquid flowing through the fine bubble liquid supply line 52 is supplied from the fine bubble liquid nozzles 33A to 33E.

The on-off valves 54A to 54E correspond to the fine bubble liquid nozzles 33A to 33E. Therefore, the controller 9 can arbitrarily select the fine bubble liquid nozzles 33A to 33E to which the fine bubble liquid should be supplied by controlling each of the on-off valves 54A to 54E.

For example, the controller 9 opens the on-off valve 54A, and closes the on-off valves 54B, 54C, 54D, 54E and the on-off valve 55 so that the fine bubble liquid is supplied only from the fine bubble liquid nozzle 33A. The controller 9 opens the on-off valve 55, and closes the on-off valves 54A, 54B, 54C, 54D, and 54E so that the fine bubble liquid is not supplied from any of the fine bubble liquid nozzles 33A to 33E, and discharged outside through the fine bubble liquid return line 53.

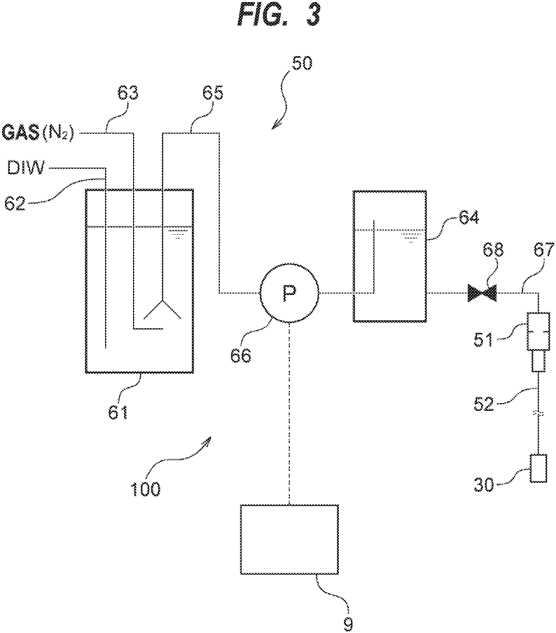

FIG. 3 is a view showing a fine bubble liquid generator. As shown in FIG. 3, the fine bubble liquid supply device 50 includes a fine bubble liquid generator 100 that generates the fine bubble liquid. The fine bubble liquid generator 100 is a device that generates the fine bubble liquid by a pressurized dissolution method for dissolving the gas into the liquid.

As shown in FIG. 3, the fine bubble liquid generator 100 includes a buffer tank 61 for storing a mixed liquid of pure water and gas, a pure water supply line 62 for supplying pure water to the buffer tank 61, and a gas supply line 63 for supplying a gas (in the embodiment shown in FIG. 3, nitrogen gas as inert gas) to the buffer tank 61. The fine bubble liquid generator 100 includes a transport line 65 connected to the buffer tank 61, a pump 66 connected to the transport line 65, and a pressurized dissolution tank 64 for storing the mixed liquid transported by driving the pump 66.

The controller 9 is electrically connected to the pump 66, and can drive the pump 66. By driving the pump 66, the mixed liquid in the buffer tank 61 is transported to the pressurized dissolution tank 64 through the transport line 65. The mixed liquid is stored in the pressurized dissolution tank 64 in a pressurized state. The fine bubble liquid generator 100 includes an introduction line 67 that introduces the pressurized mixed liquid in the pressurized dissolution tank 64 into the injection nozzle 51, and an on-off valve 68 connected to the introduction line 67. The on-off valve 68 is connected to the controller 9. When the controller 9 opens the on-off valve 68, the pressurized mixed liquid is introduced into the injection nozzle 51 through the introduction line 67.

The injection nozzle 51 includes a decompression opening portion (not shown) that generates a high pressure loss inside the injection nozzle 51. The decompression opening portion is, for example, an orifice. When the gas is sufficiently dissolved, and the pressurized mixed liquid is introduced into the injection nozzle 51, the pressure of the mixed liquid is rapidly reduced by the decompression opening portion, and the dissolved gas occurs in the mixed liquid as fine bubbles. The fine bubbles contained in the mixed liquid injected from the injection nozzle 51 are sorted into microbubbles or ultrafine bubbles by the microbubble filter 59 or the ultrafine bubble filter 58.

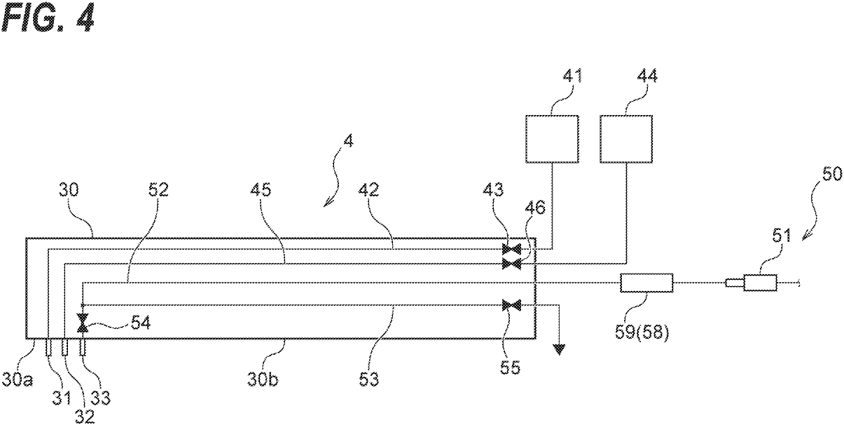

FIG. 4 is a view showing another embodiment of the fine bubble liquid supply device. As described above, the liquid supply mechanism 4 (more specifically, the fine bubble liquid supply device 50) may include one fine bubble liquid nozzle 33 and the on-off valve 54 corresponding to the fine bubble liquid nozzle 33.

As shown in FIG. 4, the fine bubble liquid supply device 50 does not necessarily include both the ultrafine bubble filter 58 and the microbubble filter 59, but rather may include either the ultrafine bubble filter 58 or the microbubble filter 59. Furthermore, the fine bubble liquid supply device 50 does not necessarily include the particle counter 60.

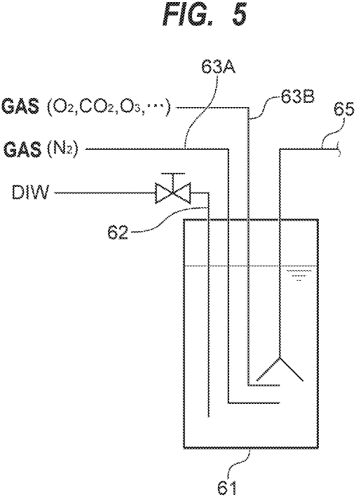

FIG. 5 is a view showing another embodiment of the fine bubble liquid generator. As shown in FIG. 5, the fine bubble liquid generator 100 may include a gas supply line 63A for supplying a first gas (e.g., nitrogen gas) to the buffer tank 61, and a gas supply line 63B for supplying a second gas (e.g., oxygen gas, carbon dioxide gas (carbonic acid gas), ozone gas) to the buffer tank 61.

Depending on structures of the substrate W to be processed, there are gas species that can be used. Therefore, the fine bubble liquid generator 100 selectively supplies the gas corresponding to the structure of the substrate W to be processed from the gas supply lines 63A, 63B. With such a configuration, the fine bubble liquid supply device 50 can supply the fine bubble liquid having bubbles generated from a gas corresponding to the structure of the substrate W among a plurality of kinds of gases.

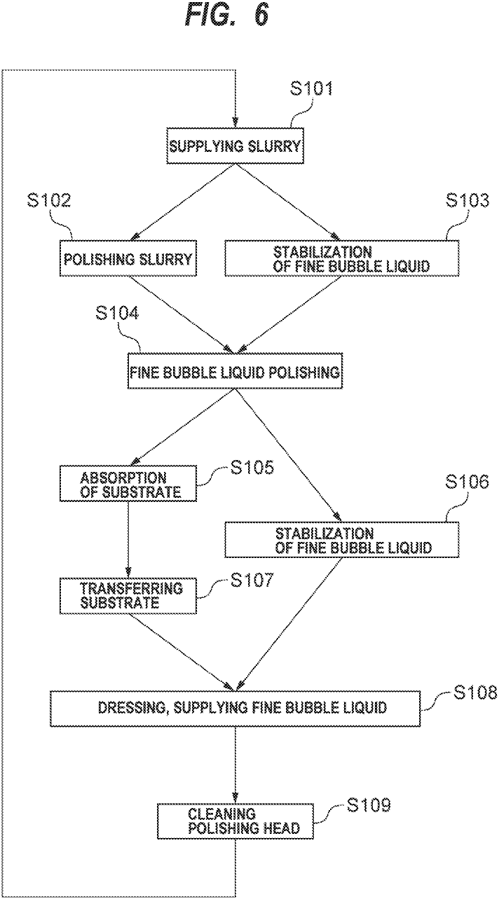

FIG. 6 is a view showing a processing flow of the substrate by the controller. The controller 9 operates the nozzle arm 30 to arrange the tip portion 30a of the nozzle arm 30 above the center CL of the polishing pad 1. The controller 9 opens the on-off valve 43 while rotating the polishing table 2 to supply the slurry onto the polishing pad 1 (see step S101 in FIG. 6). In this state, the controller 9 rotates the substrate W held by the polishing head 3, and presses the substrate W against the polishing pad 1 to slurry-polish the substrate W (see step S102). In step S102, the controller 9 polishes the substrate W by rotating the polishing pad 1 and the polishing head 3 in the same direction.

At this time, the controller 9 performs a supply preparation for stably supplying the ultrafine bubble liquid in parallel with the polishing operation (i.e., step S102) of the substrate W (see step S103). More specifically, the controller 9 operates the three-way valves 56A and 56B to open the bypass line 57 in order to supply the ultrafine bubble liquid. Then, the liquid injected from the injection nozzle 51 passes through the ultrafine bubble filter 58 without passing through the microbubble filter 59, and as a result, the fine bubble liquid supply device 50 supplies the ultrafine bubble liquid.

The controller 9 closes the on-off valves 54A to 54E, and opens the on-off valve 55, so that the ultrafine bubble liquid is discharged to the outside through the fine bubble liquid return line 53 without being supplied from the fine bubble liquid nozzles 33A to 33E. Based on the number of bubbles measured by the particle counter 60, the controller 9 determines whether or not the number of bubbles in the ultra-fine bubble liquid is stable.

Thereafter, the controller 9 closes the on-off valve 43 to finish the slurry polishing of the substrate W. After finishing the slurry polishing of the substrate W, the controller 9 starts a water polishing (in this embodiment, fine bubble liquid polishing) of the substrate W (see step S104). More specifically, the controller 9 opens at least one of the on-off valves 54A to 54E, and closes the on-off valve 55 to supply the ultrafine bubble liquid from at least one of the fine bubble liquid nozzles 33A to 33E onto the polishing pad 1.

When the ultrafine bubble liquid is supplied onto the polishing pad 1, the bubbles contained in the ultrafine bubble liquid burst. Energy (light emission, high temperature, high pressure, shock wave, etc.) is locally released by the impact of the bursting bubble, and the polishing dust and abrasive grains of the polishing liquid adhering to the surface of the substrate W are removed by this energy. Since the gas-liquid interface of the ultrafine bubble liquid has a negative potential, the ultrafine bubble liquid adsorbs and removes electrolyte ions and dirt with a positive potential.

The magnitude of the bubble impact depends on the bubble diameter. Therefore, when the fine bubble liquid supplied onto the polishing pad 1 is micro bubble liquid, the impact caused by the burst of bubbles in the micro bubble liquid is larger than the impact caused by the burst of bubbles in the ultrafine bubble liquid.

In this embodiment, the substrate W is polished with the ultrafine bubble liquid. Therefore, the impact on the substrate W caused by the bubble burst is small. Since the substrate W may have a fine structure, the damage to the substrate W can be reduced by polishing the substrate W with the ultrafine bubble liquid. As a result, defects in the substrate W can be prevented. Furthermore, this configuration does not require a longer processing time for the substrate W, and the throughput of the substrate W can be improved.

After finishing an ultrafine bubble liquid polishing the substrate W, the controller 9 closes the on-off valves 54A to 54E, and opens the on-off valve 46 to supply pure water onto the polishing pad 1. Thereafter, the controller 9 rotates the polishing table 2 and the polishing head 3, and sucks the substrate W onto the polishing head 3 (see step S105). In this state, the controller 9 raises the polishing head 3 to arrange the polishing head 3 above the polishing pad 1.

The controller 9 performs the supply preparation for stable supplying the microbubble liquid in parallel with a transport operation (i.e., step S105 and step S107 described below) of the substrate W (see step S106). More specifically, the controller 9 operates the three-way valves 56A and 56B to close the bypass line 57 while opening a portion (more specifically, upstream of the three-way valve 56A and downstream of the three-way valve 56B) of the fine bubble liquid supply line 52 in order to supply the microbubble liquid. The fine bubble liquid then passes through the microbubble filter 59, and as a result, the fine bubble liquid supply system 50 supplies microbubble liquid.

When the controller 9 closes the on-off valves 54A to 54E, and opens the on-off valve 55, the microbubble liquid is discharged to the outside through the fine bubble liquid return line 53 without being supplied from the fine bubble liquid nozzles 33A to 33E. The controller 9 determines whether or not the number of bubbles in the microbubble liquid is stable based on the number of bubbles measured by the particle counter 60.

After step S105, the controller 9 moves the polishing head 3 adsorbing the substrate W to the outside of the polishing pad 1 to transport the substrate W to the next step (see step S107). After step S107, the controller 9 supplies the microbubble liquid onto the polishing pad 1 while moving the dresser 15 onto the polishing pad 1 to dress the polishing pad 1 (see step S108).

During dressing of the polishing pad 1, the controller 9 may inject a large flow rate of cleaning liquid from the atomizer 20 arranged above the polishing pad 1 onto the surface of the polishing pad 1. In one embodiment, the flow rate of the fine bubble liquid supplied from the nozzle arm 30 is 1 L/min, and the flow rate of the fine bubble liquid supplied from the atomizer 20 is 10 L/min.

In this embodiment, the fine bubble liquid supply device 50 is configured to supply the fine bubble liquid through the nozzle arm 30. In one embodiment, the fine bubble liquid supply device 50 may be configured to supply the fine bubble liquid through the atomizer 20. With such a configuration, the fine bubble liquid supply device 50 can supply not only the fine bubble liquid through the nozzle arm 30 but also a large flow rate of the fine bubble liquid onto the polishing pad 1 through the atomizer 20. The structure for supplying the fine bubble liquid from the atomizer 20 is the same as the structure for supplying the fine bubble liquid from the nozzle arm 30, so the explanation is omitted.

During dressing of the polishing pad 1, the fine bubble liquid supply device 50 supplies the microbubble liquid onto the polishing pad 1. More specifically, the controller 9 opens at least one of the on-off valves 54A to 54E, and closes the on-off valve 55 to supply the microbubble liquid from at least one of the fine bubble liquid nozzles 33A to 33E onto the polishing pad 1.

As described above, the impact caused by the bursting of the bubbles contained in the microbubble liquid is greater than the impact caused by the bursting of the bubbles contained in the ultrafine bubble liquid. Therefore, the fine bubble liquid supply device 50 can apply a large impact to the surface (polishing surface) of the polishing pad 1 due to bursting of the bubbles.

With such a configuration, clogging of the polishing pad 1 can be eliminated more reliably. Therefore, when dressing the polishing pad 1, the amount of the polishing pad 1 to be scraped off can be reduced. As a result, the life of the polishing pad 1 can be extended, and the polishing rate and the profile of the substrate W are not adversely affected. Furthermore, dressing time can be shortened and throughput can be improved.

According to the present embodiment, the fine bubble liquid supply device 50 supplies the fine bubble liquid (i.e., ultrafine bubble liquid, microbubble liquid) having high cleaning power onto the polishing pad 1 after finishing the polishing of the substrate W. Thereby, stabilization of the polishing process of the substrate W can be realized.

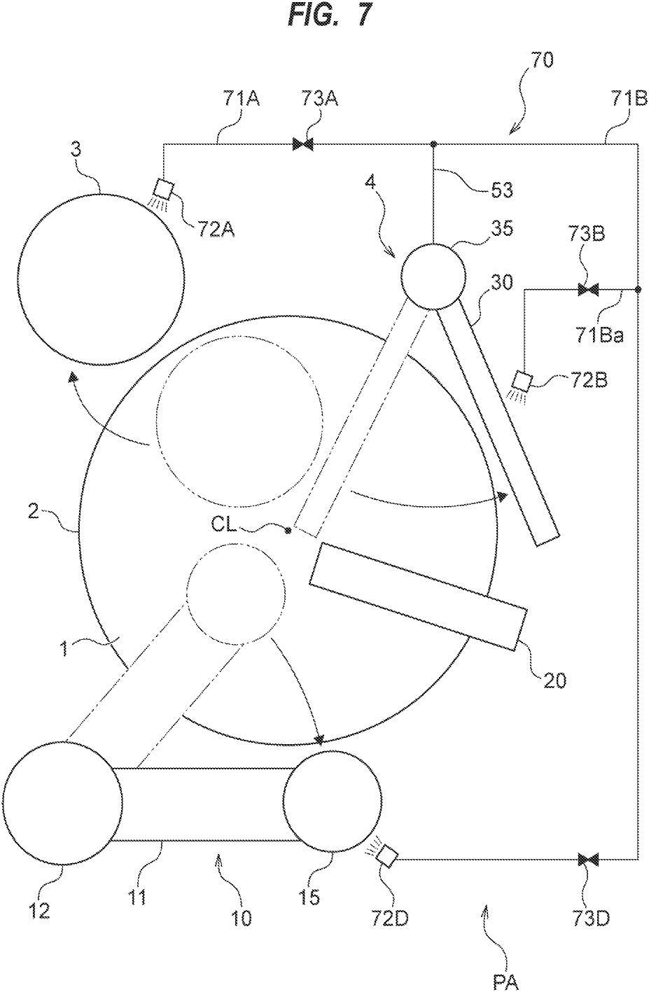

FIG. 7 is a view showing another embodiment of the polishing apparatus. As shown in FIG. 7, the polishing apparatus PA (more specifically, the fine bubble liquid supply device 50) may include a fine bubble liquid distributor 70 that distributes the fine bubble liquid to the components (in this embodiment, the polishing head 3, the liquid supply mechanism 4, and the dressing device 10) of the polishing apparatus PA.

The fine bubble liquid distributor 70 includes a distribution line 71A connected to the fine bubble liquid return line 53, a cleaning nozzle 72A connected to the distribution line 71A, and an on-off valve 73A connected to the distribution line 71A.

The cleaning nozzle 72A is arranged adjacent to the polishing head 3 in the retracted position, and the fine bubble liquid supply device 50 injects the fine bubble liquid from below the polishing head 3 toward the polishing head 3. The injecting of the fine bubble liquid with high cleaning power enables more effective cleaning of the polishing head 3.

As shown in step S109 of FIG. 6, after transporting the substrate W, the controller 9 moves the polishing head 3 to the retracted position located outside the polishing pad 1, and supplies the fine bubble liquid onto the polishing head 3 arranged in the retracted position to clean the polishing head 3. The fine bubble liquid supply device 50 cleans the polishing head 3 while the polishing head 3 is arranged in the retracted position. Therefore, the fine bubble liquid that has cleaned the polishing head 3 can be prevented from falling onto the polishing pad 1.

The on-off valve 73A is electrically connected to the controller 9. The controller 9 closes the on-off valves 54A to 54E while opening the on-off valve 55 (see FIG. 2) and the on-off valve 73A to supply the fine bubble liquid to the polishing head 3. In step S108, the fine bubble liquid supply device 50 supplies the microbubble liquid. Therefore, in step S109, the fine bubble liquid supply device 50 also supplies the microbubble liquid onto the polishing head 3.

As shown in FIG. 7, the fine bubble liquid distributor 70 may include a distribution line 71B connected to the fine bubble liquid return line 53, and cleaning nozzles 72B, 72D connected to the distribution line 71B.

The cleaning nozzle 72B is arranged adjacent to the nozzle arm 30 arranged in the retracted position. A branch line 71Ba, which is branched from the distribution line 71B, is connected to the cleaning nozzle 72B, and the on-off valve 73B is connected to the branch line 71Ba.

The cleaning nozzle 72D is arranged adjacent to the dresser 15, which is arranged in the retracted position. An on-off valve 73D connected to the distribution line 71B is arranged adjacent to the cleaning nozzle 72D.

The controller 9 can close the on-off valves 54A to 54E while opening the on-off valve 55 and the on-off valves 73B, 73D to supply the fine bubble liquid to the nozzle arm 30 and the dresser 15. For example, the controller 9 may clean at least one of the nozzle arms 30 and the dresser 15 as well as the polishing head 3 in step S109 of FIG. 6.

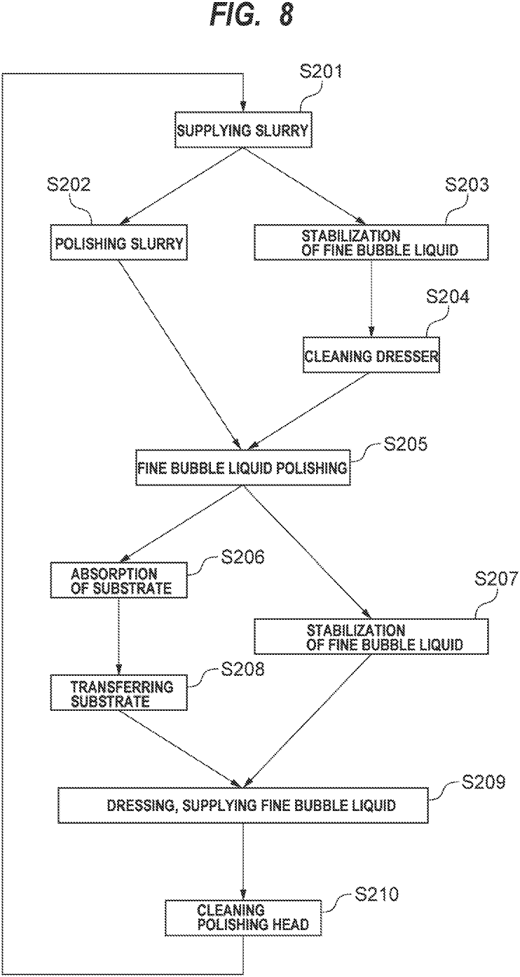

FIG. 8 is a view showing another embodiment of the processing flow of the substrate by the controller. As shown in FIG. 8, the controller 9 supplies the slurry onto the polishing pad 1 to slurry-polish the substrate W (see steps S201 and S202). The controller 9 may perform the supply preparation for stably supplying the ultrafine bubble liquid in parallel with the polishing operation (i.e., step S202) of the substrate W (see step S203), to supply the ultrafine bubble liquid to the dresser 15 through the fine bubble liquid distributor 70 (see step S204). In one embodiment, the controller 9 may clean not only the dresser 15 but also the atomizer 20.

Thereafter, the controller 9 starts the fine bubble liquid polishing of the substrate W (see step S205), and after finishing step S205, the controller 9 sucks the substrate W into the polishing head 3 (see step S206).

As shown in step S207, the controller 9 performs the supply preparation for stable supplying the microbubble liquid in parallel with the transport operation (i.e., step S206 and step S208 described below) of the substrate W. Therefore, the controller 9 transports the substrate W to the next process (see step S208), and supplies the microbubble liquid onto the polishing pad 1 to dress the polishing pad 1 (see step S209).

After transporting the substrate W, the controller 9 supplies the microbubble liquid to the polishing head 3 arranged in the retracted position to clean the polishing head 3 (see step S210). In the embodiment shown in FIG. 8, the fine bubble liquid supply device 50 cleans the dresser 15 in step S204. Therefore, the fine bubble liquid supply device 50 does not need to clean the dresser 15 in step S210.

In the embodiment described above, the configuration for supplying the fine bubble liquid discharged to the outside through the fine bubble liquid return line 53 to the components of the polishing apparatus PA has been described. The fine bubble liquid supply device 50 may include a storage tank (not shown) that stores the discharged fine bubble liquid. The fine bubble liquid supply device 50 may reuse the fine bubble liquid stored in the storage tank.

The previous description of embodiments is provided to enable a person skilled in the art to make and use the present invention. Moreover, various modifications to these embodiments will be readily apparent to those skilled in the art, and the generic principles and specific examples defined herein may be applied to other embodiments. Therefore, the present invention is not intended to be limited to the embodiments described herein but is to be accorded the widest scope as defined by limitation of the claims.

What is claimed is:

1. A polishing method comprising:
rotating a polishing table configured to support a polishing pad;
pressing a substrate held by a polishing head against the polishing pad while supplying a polishing liquid onto the polishing pad to polish the substrate; and
supplying a fine bubble liquid onto the polishing pad after finishing polishing the substrate.

2. The polishing method according to claim 1, wherein the fine bubble liquid is supplied from one or more nozzles of a nozzle arm configured to pivot in a radial direction of the polishing table onto the polishing pad.

3. The polishing method according to claim 1, comprising supplying the fine bubble liquid onto the polishing pad while pressing the substrate against the polishing pad to polish the substrate with the fine bubble liquid.

4. The polishing method according to claim 3, wherein the fine bubble liquid comprises an ultrafine bubble liquid having a bubble diameter of 1 micrometer or less.

5. The polishing method according to claim 1, comprising:
transporting the substrate from the polishing pad after finishing polishing the substrate;
moving a dresser on the polishing pad after transporting the substrate to dress the polishing pad; and
supplying the fine bubble liquid onto the polishing pad during dressing the polishing pad.

6. The polishing method according to claim 5, wherein the fine bubble liquid comprises a microbubble liquid having a bubble diameter from 1 micrometer to 100 micrometers or less.

7. The polishing method according to claim 1, wherein the fine bubble liquid is supplied from an atomizer extending in a radial direction of the polishing table onto the polishing pad.

8. The polishing method according to claim 1, comprising:
transporting the substrate from the polishing pad after finishing polishing the substrate;
moving the polishing head to a retracted position arranged outside the polishing pad after transporting the substrate; and
supplying the fine bubble liquid to the polishing head arranged in the retracted position to clean the polishing head.

9. The polishing method according to claim 1, wherein the fine bubble liquid has bubbles generated from a gas corresponding to a structure of the substrate among a plurality of kinds of gases.

10. The polishing method according to claim 9, wherein the fine bubble liquid is generated by a pressurized dissolution method for dissolving the gas into a liquid.

11. The polishing method according to claim 1, comprising: counting the number of bubbles contained in the fine bubble liquid by a particle counter; and
supplying the fine bubble liquid after the number of bubbles reaches a predetermined reference number.

12. A polishing apparatus comprising:
a polishing table configured to support a polishing pad;
a polishing head configured to press a substrate against the polishing pad;
a liquid supply mechanism configured to supply a liquid onto the polishing pad, the liquid supply mechanism comprising a fine bubble liquid supply device configured to supply a fine bubble liquid onto the polishing pad after finishing polishing the substrate; and
a controller configured to control an operation of the liquid supply mechanism.

13. The polishing apparatus according to claim 12, wherein the fine bubble liquid supply device comprises:
a nozzle arm configured to pivot in a radial direction of the polishing table; and
one or more fine bubble liquid nozzles, arranged to the nozzle arm, configured to supply the fine bubble liquid onto the polishing pad.

14. The polishing apparatus according to claim 12, wherein the fine bubble liquid supply device is configured to supply an ultrafine bubble liquid, as the fine bubble liquid, having a bubble diameter of 1 micrometer or less onto the polishing pad while pressing the substrate against polishing pad by the polishing head.

15. The polishing apparatus according to claim 12, wherein the polishing apparatus comprises a dressing device configured to dress the polishing pad, and electrically connected to the controller,
wherein the controller moves a dresser on the polishing pad by operating the dressing device to dress the polishing pad after finishing polishing the substrate and transporting the substrate, and
wherein the fine bubble liquid supply device supplies a microbubble liquid, as the fine bubble liquid, having a bubble diameter from 1 micrometer to 100 micrometers or less onto the polishing pad during dressing the polishing pad.

16. The polishing apparatus according to claim 12, wherein the polishing apparatus comprises an atomizer extending in a radial direction of the polishing table, and
wherein the fine bubble liquid supply device supplies the fine bubble liquid from the atomizer onto the polishing pad.

17. The polishing apparatus according to claim 12, wherein the controller moves the polishing head to a retracted position arranged outside the polishing pad after finishing polishing the substrate and transporting the substrate, and
the fine bubble liquid supply device supplies the fine bubble liquid to the polishing head arranged in the retracted position to clean the polishing head.

18. The polishing apparatus according to claim 12, wherein the fine bubble liquid has bubbles generated from a gas corresponding to a structure of the substrate among a plurality of kinds of gases.

19. The polishing apparatus according to claim 18, wherein the fine bubble liquid supply device comprises a fine bubble liquid generator configured to generate the fine bubble liquid by a pressurized dissolution method for dissolving the gas into a liquid.

20. The polishing apparatus according to claim 12, wherein the fine bubble liquid supply device comprises a particle counter configured to count the number of bubbles contained in the fine bubble liquid, and
wherein the fine bubble liquid supply device supplies the fine bubble liquid after the number of bubbles reaches a predetermined reference number based on the number of bubbles counted by the particle counter.
